(19) United States
(12) Patent Application Publication
(10) Pub. No.: US 2019/0150313 A1
(43) Pub. Date: May 16, 2019

(54) Modular Computer Room for Servers

(71) Applicant: Suzhou A-Rack Enclosure Systems Co., Ltd., Suzhou, Jiangsu (CN)

(72) Inventor: ZhiYong Ding, Suzhou New District, Jiangsu Province (CN)

(21) Appl. No.: 15/429,607

(22) PCT Filed: Sep. 29, 2016
(86) PCT No.: PCT/CN2016/100777

§ 371 Date: Feb. 10, 2017

(30) Foreign Application Priority Data
Jul. 28, 2016 (CN) 201610626174.8

(51) Int. Cl. H05K 7/14; H05K 5/03; H05K 5/00; H05K 5/02

(52) U.S. Cl. CPC H05K 7/1497; H05K 7/1487; H05K 5/0221; H05K 5/0008; H05K 5/03

(57) ABSTRACT

The present invention discloses a modular computer room for servers, wherein the said modular computer room for servers consists of top cover (1), cabinet module (2), front open door (3), rear open door (4) and air conditioning module (5) and staircase (6). The technical solution in accordance with this utility model provides a modular design with lower cost, better cooling results and lower power consumption by the equipment.

### FIELD

The present invention relates to the field of communication equipment, and particularly relates to a modular computer room for servers.

### BACKGROUND

Currently, it is a development trend to build in the future, a multifunctional computer room integrated with communication equipment, power supply and distribution system, refrigeration system and computer room settings. “Comfort, smart, energy-saving, environmental compliance and integration” have become primary indicators in the construction of a computer room for servers. With the rapid development of the network technology, the volume of computer processing equipment is getting smaller and smaller, while the powers thereof are becoming higher and higher. As such, for ensuring a safe operation of the computer room, the ventilation, cooling and energy-efficiency have become a greater challenge. Usually, a conventional computer room needs installation of various cables, ducts and conduits as well as refrigeration and power distribution equipment, such a model of which occupies a lot of space and is a huge waste for some companies, in which only a small computer room is required. Furthermore, in prior arts, the whole computer room cooling by means of refrigeration leads to a lower refrigeration efficiency and higher power consumption. The present invention is envisaged for the reasons enumerated above.

### DESCRIPTION

It is an object of the present invention to provide a modular computer room to solve the problems encountered by small companies during the construction of a computer room with refrigeration cooling.

To solve such problems of the prior arts, the technical solution provided in accordance with the present invention includes:

A modular computer room for servers, wherein the said modular computer room for servers consists of the top cover, cabinet module, front open door, rear open door, air conditioning module and staircase.

Preferably, the said top cover, cabinet module, front open door, rear open door and air conditioning module altogether form a cooling passage.

Preferably, an electronic code lock is mounted on the said rear open door.

Preferably, the said air conditioning module consists of a refrigeration unit and a fan.

Preferably, the said top cover, cabinet module, front open door, rear open door, air conditioning module and staircase are assembled and secured by means of screws.

Preferably, the said cabinet module is a cabinet for servers assembled by screws.

Compared with the technical solutions of the prior arts, the technical advancements offered by the present invention include the realization of:
1. A modular design and lower cost for the computer room for servers provided by the technical solution in accordance with the present invention;
2. An integrated design for the cooling unit and the computer room with better cooling results and lower power consumption provided by the technical solution in accordance with the present invention.

### DESCRIPTION OF THE ACCOMPANYING DRAWING

The present invention will be further described below in relation to the accompanying drawings and an exemplary embodiment:

FIG. 1 is an exemplary illustration of the structure of a modular computer room for servers configured in accordance with one of embodiments of the present invention;

FIG. 2 is the isometric view of a modular computer room for servers configured in accordance with one of embodiments of the present invention;

FIG. 3 is the front view of a modular computer room for servers configured in accordance with one of embodiments of the present invention;

FIG. 4 is the left side view of a modular computer room for servers configured in accordance with one of embodiments of the present invention;

FIG. 5 is the top view of a modular computer room for servers configured in accordance with one of embodiments of the present invention;

FIG. 6 is an exemplary illustration of the structure of the air conditioning module configured in accordance with one of embodiments of the present invention;

FIG. 7 is an exemplary illustration of the wind direction configured in accordance with one of embodiments of the present invention.

Wherein, 1 is the top cover, 2 is the cabinet module, 3 is the front open door, 4 is the rear open door, 5 is the air conditioning module, 6 is the staircase, 7 is the cooling passage, 41 is the electronic code lock, 51 is the refrigeration unit and 52 is the fan.

### EMBODIMENTS

The abovementioned embodiment is further described below in conjunction with the specific example. It should be understood that such examples are used to explain the present invention, and are not intended to limit the scope of the present invention. The implementation conditions in the example can be further adjusted in compliance with the requirements by a specific manufacturer and the non-indicated implementation conditions are usually those in a conventional experiment.

### Example

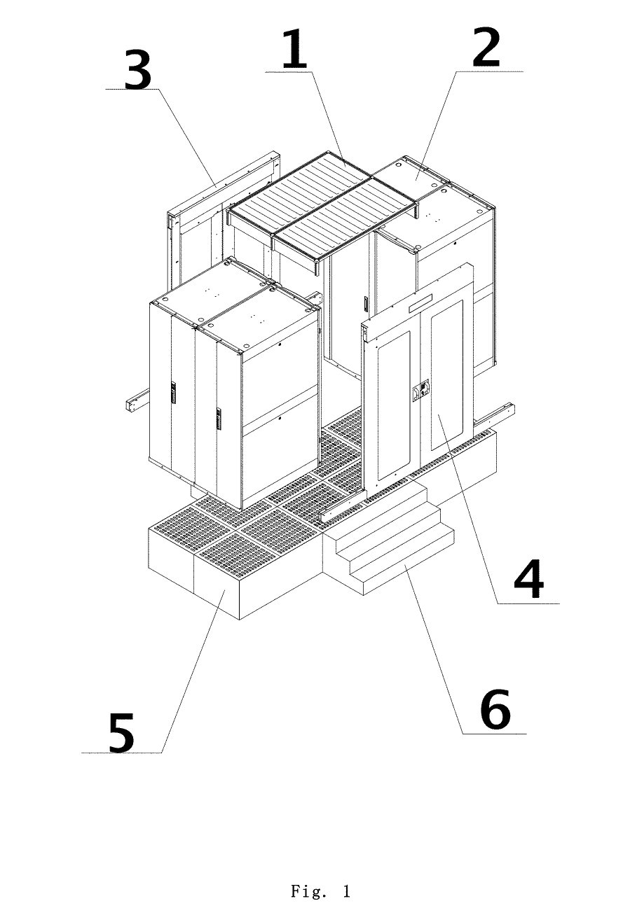

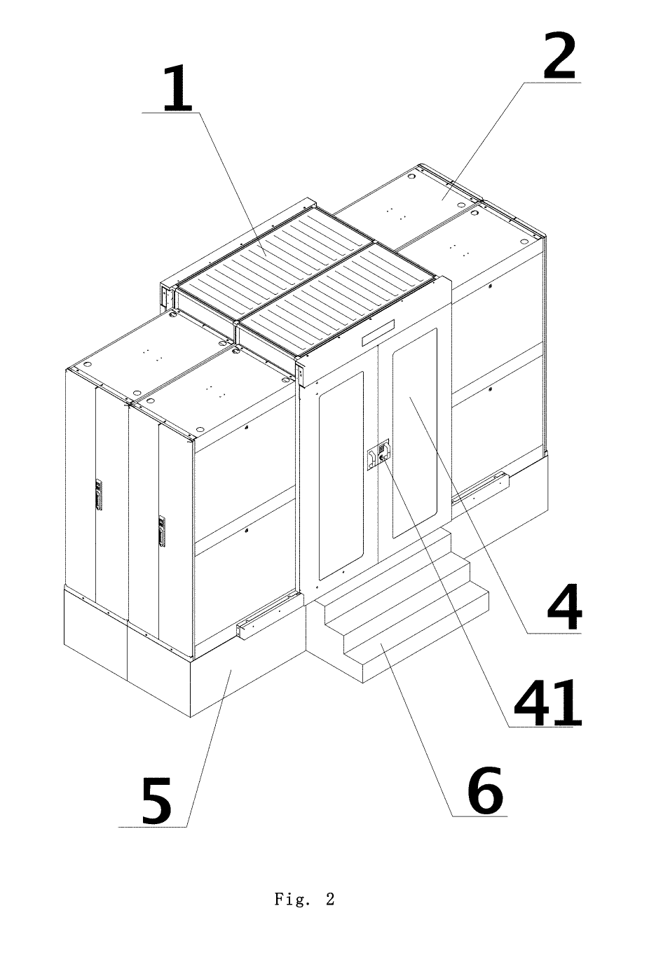

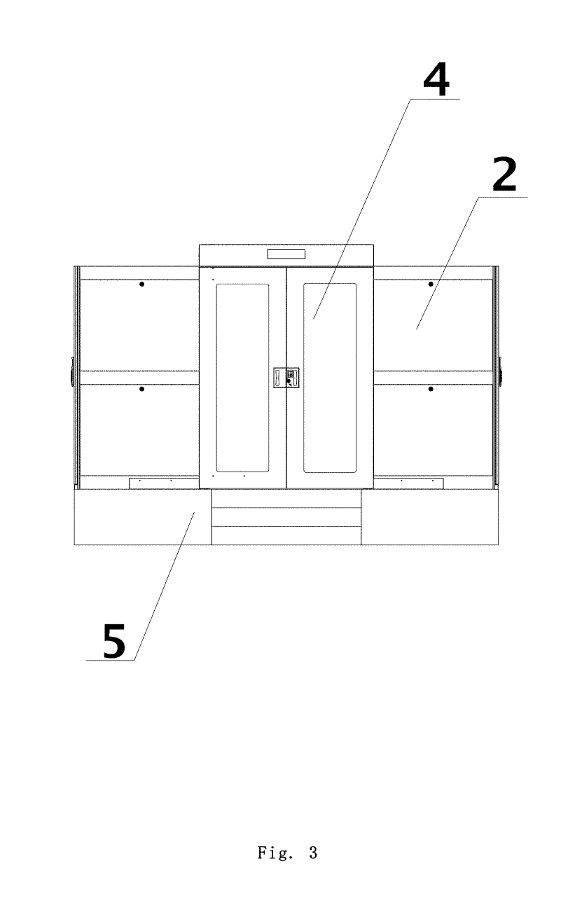

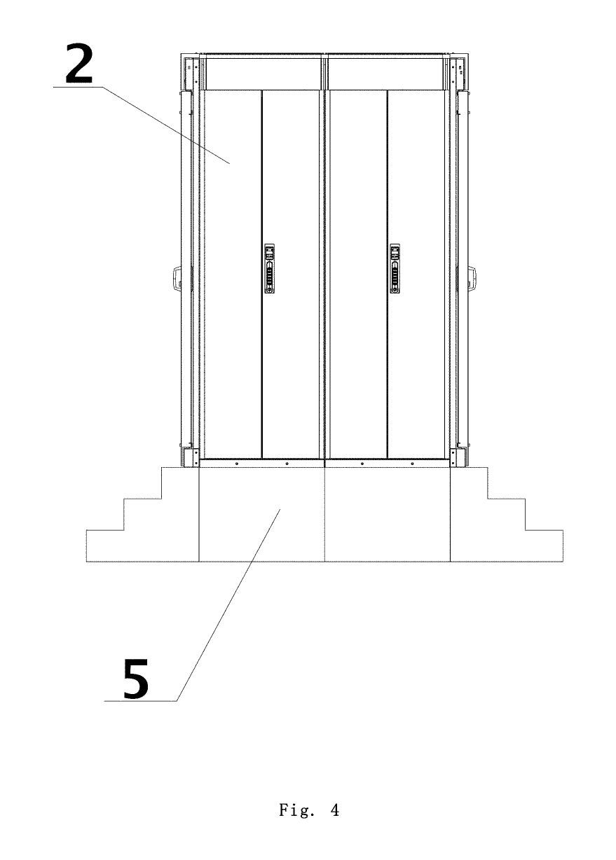

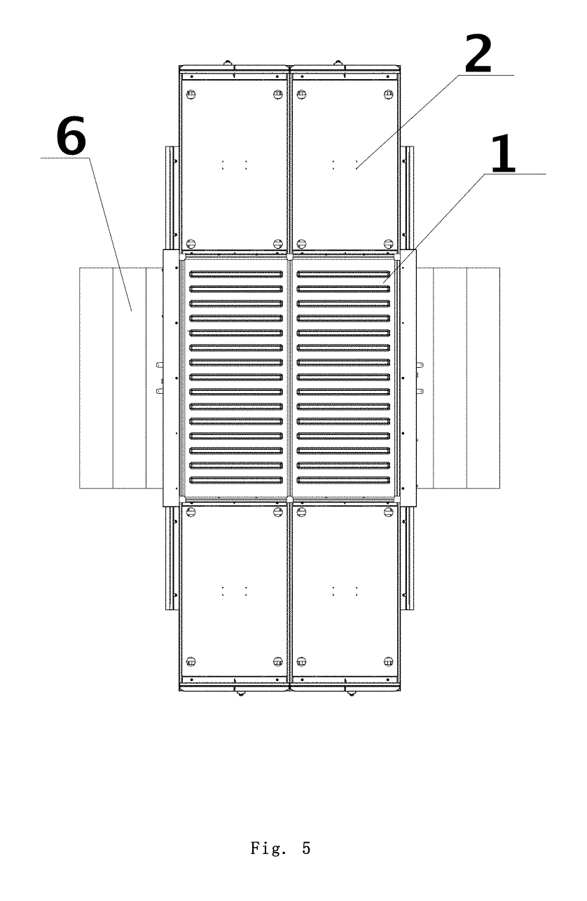

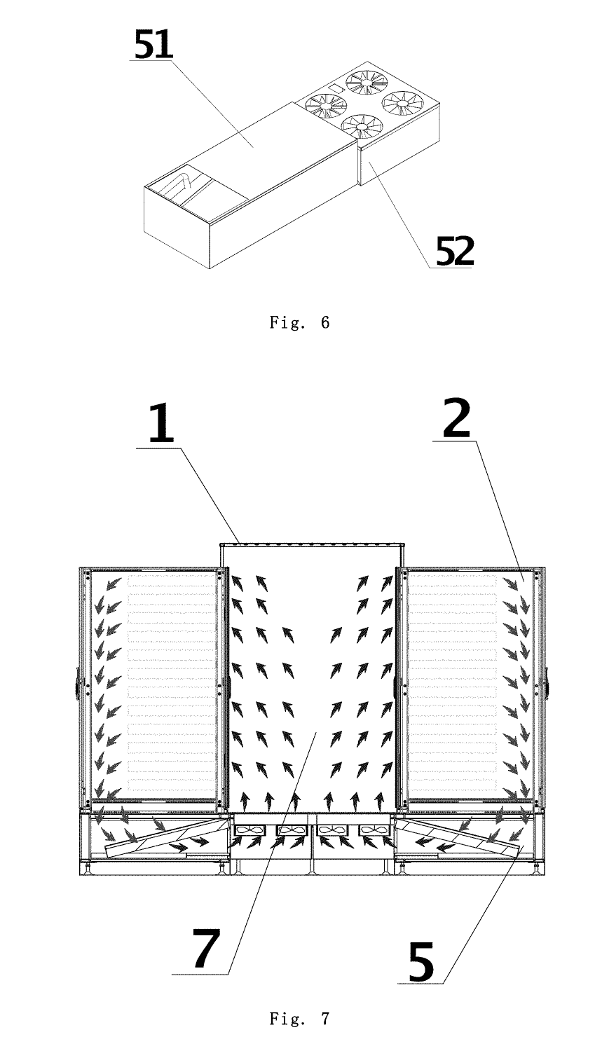

As shown in FIG. 1-6, a modular computer room for servers consists of top cover 1, cabinet module 2, front open door 3, rear open door 4, air conditioning module 5 and staircase 6. This modular computer room uses an integral and modular design, whereby the number of modules can be increased or decreased during the construction of the computer room to meet the requirements and lower the cost, as necessary.

Top cover 1, cabinet module 2, front open door 3, rear open door 4 and air conditioning module 5 altogether comprise a cooling passage 7. The heat produced by the electronic equipment in the computer room is taken away by air conditioning module 5 during the refrigeration operation in the computer room while the cooling wind is taken into cooling passage 7 to cool the electronic equipment in cabinet module 2, resulting in cycles of exchange between hot and cold airs with better refrigerating effects and lower power consumption.

Electronic code lock 41 is mounted on rear open door 4.

Air conditioning module 5 consists of refrigeration unit 51 and fan 52.

Top cover 1, cabinet module 2, front open door 3, rear open door 4, air conditioning module 5 and staircase 7 are assembled and secured by means of screws.

Cabinet module 2 is a cabinet for servers assembled by screws.

The example as described above has been presented only for explanation of technical constructions and characteristics in accordance with the present invention, in order to enable those skilled in the art to understand the disclosures of the present invention and practice the same accordingly, however it is not intended to limit the scope of the present invention. The accompanying claims and their equivalents are intended to cover any variations and modifications as that would fall within the scope and spirit of the present invention.

What is claimed is:

1. A modular computer room for servers, wherein the said modular computer room for servers consists of top cover (1), cabinet module (2), front open door (3), rear open door (4), air conditioning module (5) and staircase (6).

2. A modular computer room for servers as claimed in claim 1, wherein the said top cover (1), cabinet module (2), front open door (3), rear open door (4) and air conditioning module (5) altogether consist of cooling passage (7).

3. A modular computer room for servers as claimed in claim 1, wherein the said rear open door (4) is mounted with electronic code lock (41).

4. A modular computer room for servers as claimed in claim 1, wherein the said air conditioning module (5) consists of refrigeration unit (51) and fan (52).

5. A modular computer room for servers as claimed in claim 1, wherein the said top cover (1), cabinet module (2), front open door (3), rear open door (4), air conditioning module (5) and staircase (6) are assembled and secured by means of screws.

6. A modular computer room for servers as claimed in claim 1, wherein the said cabinet module (2) is a cabinet for servers assembled by screws.
